(19) United States
(12) Patent Application Publication
(10) Pub. No.: US 2016/0380628 A1
(43) Pub. Date: Dec. 29, 2016

(54) Keyboard Assembly

(71) Applicant: SUNREX TECHNOLOGY CORP., Taichung City (TW)

(72) Inventor: Hsi-Chang Chu, New Taipei City (TW)

(21) Appl. No.: 15/188,227

(22) Filed: Jun. 21, 2016

(30) Foreign Application Priority Data
Jun. 23, 2015 (TW) 104210041

(51) Int. Cl. H03K 17/98; H01H 13/70; H03M 11/20; H01H 41/14

(52) U.S. Cl. CPC H03K 17/98; H01H 41/14; H01H 13/70; H03M 11/20

(57) ABSTRACT

A keyboard assembly includes a plurality keycaps, a plurality of sensor units and a control unit. The sensor units correspond respectively to the keycaps, and each of the sensor units is to output a pressure signal indicating magnitude of a pressure applied to a corresponding keycap. The control unit is configured to receive the pressure signal, and to determine a current repetition rate according to the pressure signal. When one keycap is depressed, the control unit repeatedly outputs a key code corresponding to the keycap at the current repetition rate while the keycap was depressed, and outputs the key code once while the keycap was not depressed.

### CROSS-REFERENCE TO RELATED APPLICATION

This application claims priority of Taiwanese Patent Application No. 104210041, filed on Jun. 23, 2015.

### FIELD

The disclosure relates to an input device, more particularly to a keyboard assembly.

### BACKGROUND

A conventional input device, such as a keyboard, a mouse or a track ball, is to output a key code corresponding to a button to a computer when the button is depressed. For example, when a button of the keyboard is depressed, the keyboard performs matrix scanning to detect which button is depressed and sends a key code corresponding to the depressed button to the computer, so an application program that is currently used can receive the key code. However, when the button is held, the keyboard may only output the key code repeatedly at a predetermined fixed repetition rate until the button is released.

### SUMMARY

Therefore, an object of the disclosure is to provide a keyboard assembly that can output a key code at a changeable repetition rate.

According to the disclosure, a keyboard assembly comprises a keyboard, a plurality of sensor units and a control unit.

The keyboard includes a chassis, and a plurality of keycaps disposed on the chassis.

The sensor units are disposed at the chassis, and correspond respectively to the keycaps. Each of the sensor units is configured to sense a pressure applied to a corresponding one of the keycaps and to output a pressure signal indicating magnitude of the pressure.

The control unit is coupled to the sensor units, and includes a detecting module, a rate determining module and a control module.

The detecting module is configured to receive the pressure signal from each of the sensor units, and to output a current pressure value corresponding to the pressure signal upon receipt of the pressure signal.

The rate determining module is coupled to the detecting module for receiving the current pressure value therefrom, and is configured to output a current repetition rate according to the current pressure value.

The control module is coupled to the rate determining module for receiving the current repetition rate therefrom, and is configured to output a plurality of key codes corresponding respectively to the keycaps.

When one of the keycaps is being depressed, the control module is further configured to detect whether the one of the keycaps was previously depressed, to repeatedly output a corresponding one of the key codes at the current repetition rate while the one of the keycaps was previously depressed, and to output the corresponding one of the key codes once while the one of the keycaps was not previously depressed.

### BRIEF DESCRIPTION OF THE DRAWINGS

Other features and advantages of the disclosure will become apparent in the following detailed description of the embodiment with reference to the accompanying drawings, of which:

FIG. 1 is a partially sectional view of a keyboard assembly of an exemplary embodiment according to the disclosure;

FIG. 2 is a block diagram illustrating the keyboard assembly of the exemplary embodiment according to the disclosure;

FIGS. 3 and 4 are partially sectional views illustrating a keycap depressed with different pressures;

FIGS. 5 and 6 illustrate different repetition rates at which the keyboard assembly outputs an input code; and

FIG. 7 is a flow chart illustrating operation of the keyboard assembly of the exemplary embodiment according to the disclosure.

### DETAILED DESCRIPTION

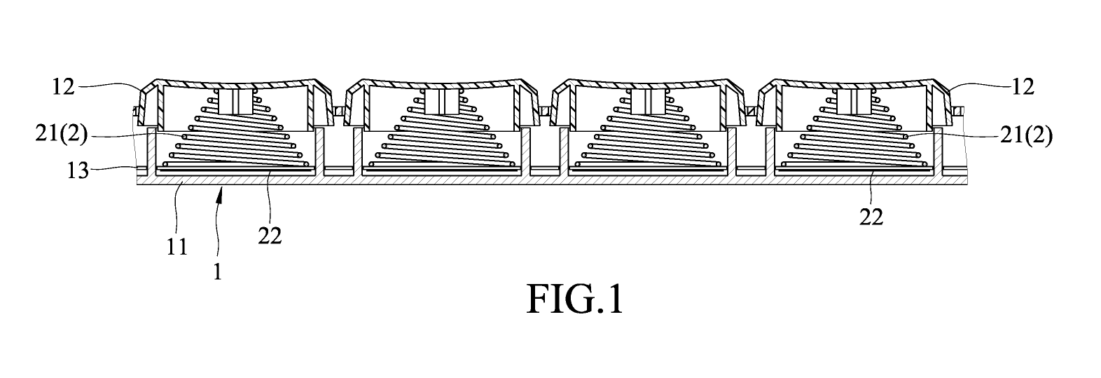

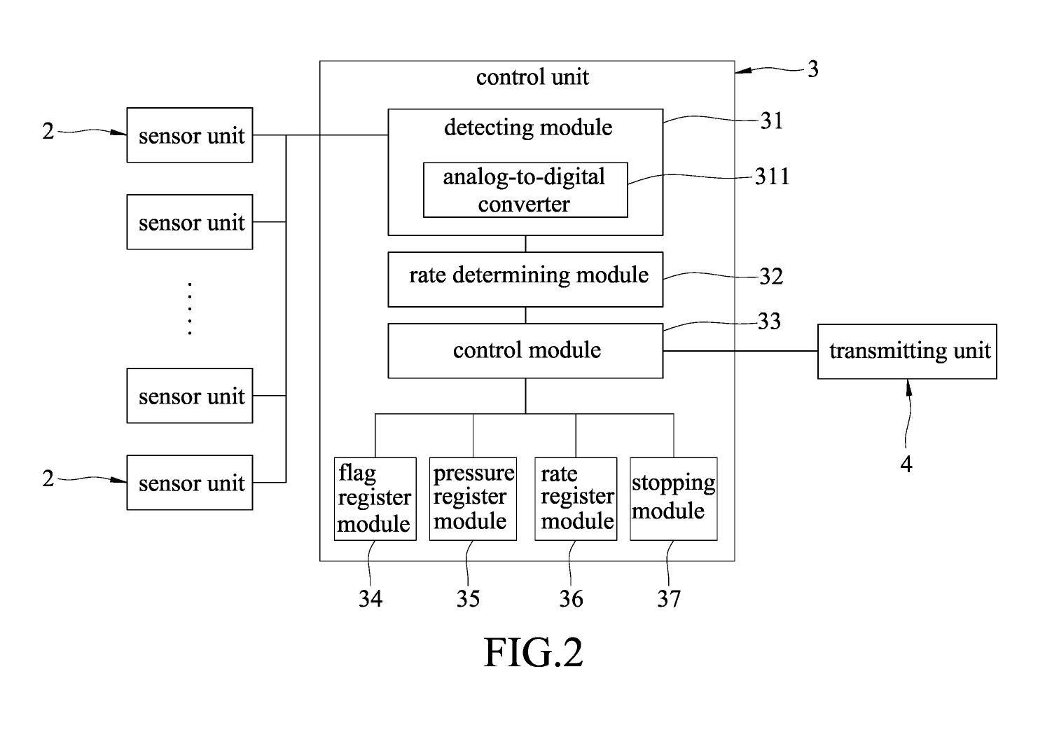

Referring to FIGS. 1 and 2, the exemplary embodiment of a keyboard assembly according to the present disclosure includes a keyboard 1, a plurality of sensor units 2, a control unit 3 and a transmitting unit 4.

The keyboard 1 includes a chassis 11, a plurality of keycaps 12 disposed on the chassis 11, and a circuit board 13 disposed on the chassis 11 and under the keycaps 12. Since architecture of the keyboard 1 is well known in the art, details thereof will be omitted herein and FIG. 1 is merely illustrated as a schematic diagram. It should be understood that the keycaps 12 can slidably move downward and upward when being depressed and released along a travel path defined by a stem or a scissor switch (not shown in the figures). In addition, the circuit board 13 can be a rigid print circuit board (PCB) or a flexible PCB.

The sensor units 2 are disposed at the chassis 11 and correspond respectively to the keycaps 12. Each of the sensor units 2 includes a coil spring 21 disposed under a corresponding one of the keycaps 12, and a capacitance detecting element 22 located beneath the coil spring 21 and on the circuit board 13. When a pressure is applied on one of the keycaps 12, the depressed one of the keycaps 12 moves downward and compresses the coil spring 21 toward the capacitance detecting element 22. The compressed length of the compressing coil spring 21 toward the capacitance detecting element 22 is directly proportional to the pressure applied on the corresponding one of the keycaps 12.

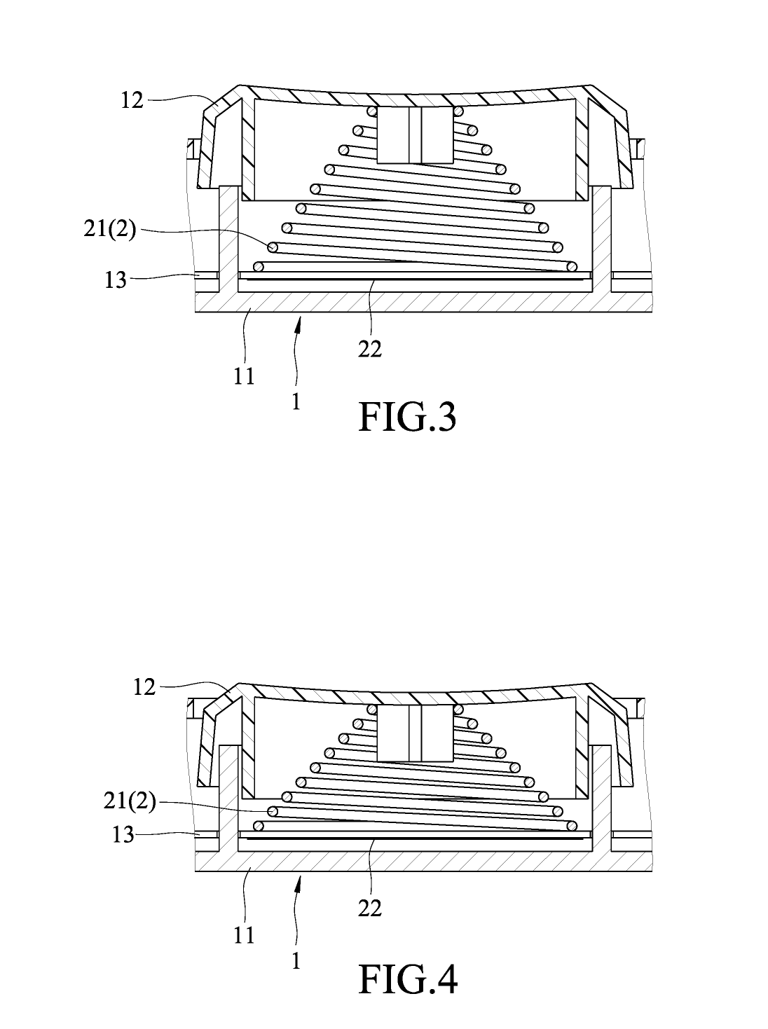

FIGS. 3 and 4 illustrate one of the keycaps being depressed by different pressures, respectively. As shown in FIG. 4, when a higher pressure is applied to the keycap 12, the compressed length of the compressing coil spring 21 toward the capacitance detecting element 22 increases accordingly. As a result, inductive capacitance sensed by the capacitance detecting element 22 increases. In this way, the inductive capacitance sensed by the capacitance detecting element 22 is directly proportional to the pressure applied to the keycap 12. As a result, the capacitance detecting element 22 of the sensor unit 2 is configured to sense the pressure applied to the keycap 12 and to output a pressure signal indicating magnitude of the pressure.

Referring back to FIG. 2, the control unit 3 is electrically connected to the sensor units 2, and includes a detecting module 31, a rate determining module 32, a control module 33, a flag register module 34, a pressure register module 35, a rate register module 36 and a stopping module 37.

The detecting module 31 includes an analog-to-digital converter (ADC) 311. The ADC 311 is to receive the pressure signal from each of the sensor units 2, and to convert the pressure signal into a current pressure value corresponding to the pressure signal, and to output the current pressure value. Specifically, the current pressure value corresponds to the magnitude of the pressure.

The rate determining module 32 is coupled to the detecting module 31 for receiving the current pressure value from the detecting module 31, and is configured to output a current repetition rate according to the current pressure value. The current repetition rate is directly proportional to the pressure applied on the depressed one of the keycaps 12. Namely, the rate determining module 32 increases the current repetition rate with the increasing of the current pressure value.

The control module 33 is coupled to the rate determining module 32 for receiving the current repetition rate therefrom, and is configured to output a plurality of key codes corresponding respectively to the keycaps 12. When one of the keycaps 12 is being depressed, the control module 33 is further configured to detect whether the one of the keycaps 12 was previously depressed, to repeatedly output a corresponding one of the key codes that corresponds to the one of the keycaps 12 at the current repetition rate while the one of the keycaps 12 was previously depressed, and to output the corresponding one of the key codes once while the one of the keycaps 12 was not previously depressed.

The flag register module 34 is coupled to the control module 33, and stores a plurality of flags that correspond to the keycaps 12, respectively. Each of the flags indicates whether a corresponding one of the keycaps 12 was depressed or not. The control module 33 is configured to determine whether each of the keycaps 12 was depressed according to a respective one of the flags. The control module 33 is further configured to determine whether to update one of the flags stored in the flag register 34 according to the current pressure value that corresponds to the pressure signal from the sensor unit 2 corresponding to the keycap 12 which corresponds to said one of the flags.

The pressure register module 35 is coupled to the control module 33, and stores a plurality of previous pressure values corresponding to the keycaps 12, respectively. Each of the previous pressure values was previously obtained by the detecting module 31 according to the pressure signal that was outputted by a corresponding one of the sensor units 2 when a corresponding one of the keycaps 12 was depressed. The control module 33 is further configured to determine whether to update one of the previous pressure values stored in the pressure register module 35 according to the comparison between said one of the previous pressure values and the current pressure value that corresponds to the pressure signal from the sensor unit 2 corresponding to the keycap 12 which corresponds to said one of the previous pressure values.

The rate register module 36 is coupled to the control module 33, and stores a plurality of previous repetition rates corresponding to the keycaps 12, respectively. Each of the previous repetition rates was previously obtained by the rate determining module 32 when a corresponding one of the keycaps 12 was depressed. The control module 33 is further configured to determine whether to update one of the previous repetition rates stored in the rate register module 36 according to the current pressure value outputted by the detecting module 31 and one of the flags corresponding to the keycap 12 that corresponds to said one of the previous repetition rates.

The stopping module 37 is coupled to the control module 33, and is configured to store a predetermined value, to receive the current pressure value, and to output a stop signal to the control module 33 for stopping the control module 33 from outputting the corresponding one of the key codes when the current pressure value is smaller than the predetermined value.

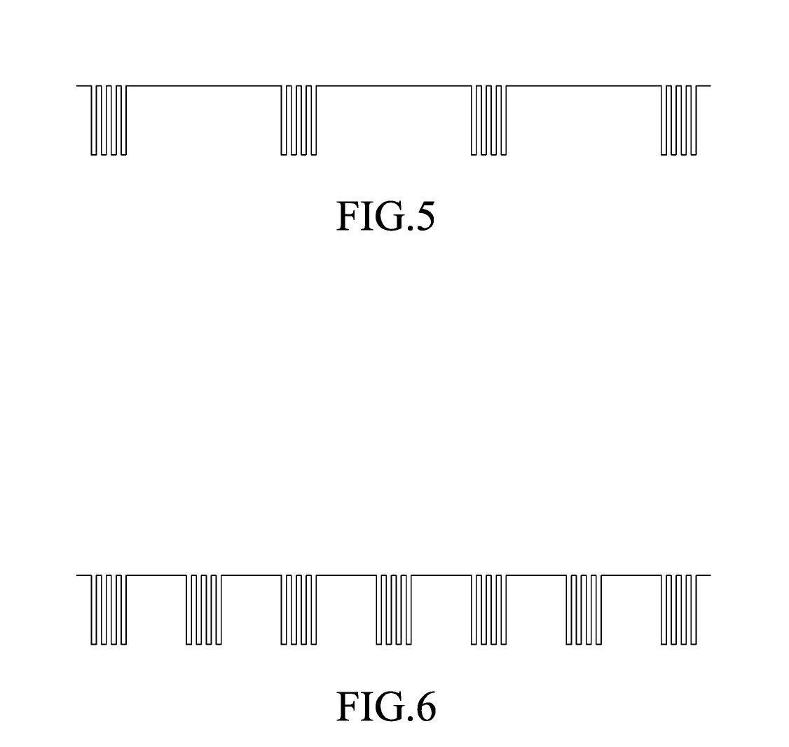

FIGS. 5 and 6 illustrate different repetition rates corresponding to different pressure values outputted by the detecting module 31. As shown in FIG. 5, when a lower pressure is applied to one of the keycaps 12 (i.e., a smaller pressure value), the control module 33 repeatedly outputs a corresponding key code at a slower repetition rate. As shown in FIG. 6, when a higher pressure is applied to one of the keycaps 12 (i.e., a greater pressure value), the control module 33 repeatedly outputs a corresponding key code at a faster repetition rate.

The transmitting unit 4 is electrically connected to the control module 33 of the control unit 3 for receiving the key code outputted thereby, and is configured to output an input signal corresponding to the key code to a back-end device (such as a computer) electrically connected thereto.

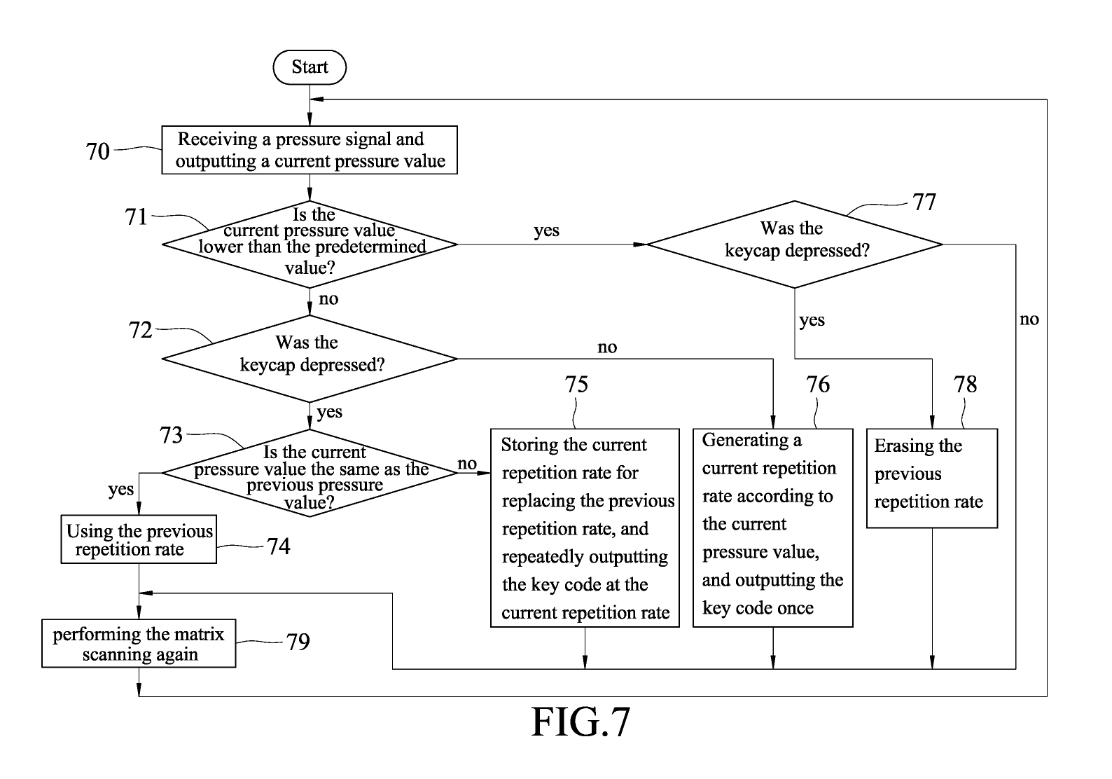

FIG. 7 is a flow chart illustrating operation of the control unit 3.

First of all, the control unit 3 performs matrix scanning on the sensor units 2 for recognizing which one of the keycaps 12 is depressed. When one of the keycaps 12 is depressed, the detecting module 31 receives the pressure signal outputted by the sensor unit 2 corresponding to the depressed one of the keycaps 12, and executes analog-to-digital conversion on the pressure signal so as to output the current pressure value (step 70). Since detail of the matrix scanning is well known by those skilled in the art, it will be omitted herein for the sake of brevity.

Then, the stopping module 37 receives the current pressure value from the detecting module 31, and determines whether the current pressure value is smaller than the predetermined value (step 71). When the current pressure value is not smaller than the predetermined value, it means that the corresponding one of the keycaps 12 is depressed and is triggered, and the control module 33 sequentially determines whether a corresponding one of the flags indicates the depressed one of the keycaps 12 was depressed (step 72). When the determination in step 72 is affirmative, it means that the depressed one of the keycaps 12 was depressed at the last time when the control unit 3 performs the matrix scanning, and the control module 33 receives from the detecting module 31 the current pressure value that corresponds to the pressure applied to the depressed one of the keycaps 12 in the current matrix scanning, and compares the current pressure value with a corresponding one of the previous pressure values that is stored in the pressure register module 35 and that corresponds to the pressure applied to the depressed one of the keycaps 12 in the last matrix scanning (step 73).

When the current pressure value is the same as the previous pressure value, the control module 33 repeatedly outputs the key code corresponding to the depressed one of the keycaps 12 at the previous repetition rate that is stored in the rate register module 36 and that corresponds to the depressed one of the keycaps 12 (step 74). When the current pressure value is not the same as the previous pressure value, the control module 33 receives the current repetition rate from the rate determining module 32, stores the current repetition rate in the rate register module 36 for replacing the previous repetition rate, and repeatedly outputs the key code at the current repetition rate (step 75).

In another situation, when the determination in step 72 is negative, it means that the depressed one of the keycaps 12 was not depressed at the last time when the control unit 3 performs the matrix scanning, the rate determining module 32 receives the current pressure value from the detecting module 31 and outputs the current repetition rate. Then, the control module 33 receives the current repetition rate, updates the previous repetition rate stored in the rate register module 36 with the current repetition rate, updates the corresponding one of the flags to indicate that the depressed one of the keycaps 12 was depressed, and outputs the key code once (step 76).

In yet another situation, when it is determined in step 71 that the current pressure value is smaller than the predetermined value, it means that the depressed one of the keycaps 12 is not triggered, and the control module 33 sequentially determines whether the corresponding one of the flags indicates the depressed one of the keycaps 12 was depressed (step 77). When the determination in step 77 is affirmative, it means that the depressed one of the keycaps 12 was depressed in the last matrix scanning and is not depressed in this matrix scanning. Then, the control module 33 erases the previous repetition rate stored in the rate register 36 and corresponding to the depressed one of the keycaps 12, and updates the corresponding one of the flag to indicate that the depressed one of the keycaps 12 is not depressed, and the stopping module 37 outputs the stop signal to stop the control module 33 from outputting the key code (step 78).

In still yet another situation, when the determination in step 77 is negative, it means that the depressed one of the keycaps 12 was not depressed in both the last matrix scanning and in the present matrix scanning. The control module 33 keeps the corresponding one of the flags to indicate that the depressed one of the keycaps 12 was not depressed, and the stopping module 37 outputs the stop signal to stop the control module 33 from outputting the key code. Then again, the control unit 3 performs the matrix scanning on the sensor units 2 for recognizing which one of the keycaps 12 is depressed (step 79), and repeats the method of FIG. 7 according to the scanning result.

In sum, when one of the sensor units 2 senses the pressure applied to the corresponding one of the keycaps 12 and outputs the pressure signal indicating the magnitude of the pressure, the detecting module 31 receives the pressure signal and outputs the current pressure value corresponding to the pressure signal, the rate determining module 32 receives the current pressure value and outputs the current repetition rate corresponding to the current pressure value, and the control module 33 repeatedly outputs the corresponding key code at the current repetition rate. Accordingly, the current repetition rate changes when any slight change of the pressure applied to the keycap 12 is sensed by the sensor unit 2. Thus, the back-end device can perform different operations in response to the pressure that users apply to the keycaps 12. Especially in the application of gaming devices, by fully reflecting any slight changes on the pressure that the users apply to the keyboard assembly of this disclosure, the users can obtain better gaming experiences.

In addition, with the simple combination of the coil spring 21 and the capacitance detecting element 22, each of the sensor units 2 not only has a simple structure and good durability but also has a relatively low cost.

Further, by cooperating with the control module 33, the flag register module 34, the pressure register module 35 and the rate register module 36, the control module 33 may directly fetch the previous repetition rate stored in the rate register module 35 for repeatedly outputting the key code without receiving the current repetition rate generated by the rate determining module 32. In this way, the process for determining the repetition rate can be simplified.

Moreover, by virtue of the stopping module 37 for determining whether the current pressure value is smaller than the predetermined value, anti-noise control of the control module 33 is enhanced. In other words, inadvertent touches on the keycaps 12 may not be responded.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects.

While the disclosure has been described in connection with what is considered the exemplary embodiment, it is understood that this disclosure is not limited to the disclosed embodiment but is intended to cover various arrangements included within the spirit and scope of the broadest interpretation so as to encompass all such modifications and equivalent arrangements.

What is claimed is:

1. A keyboard assembly comprising:
a keyboard including a chassis, and a plurality of keycaps disposed on said chassis;
a plurality of sensor units disposed at said chassis and corresponding respectively to said keycaps, each of said sensor units being configured to sense a pressure applied to a corresponding one of said keycaps and to output a pressure signal indicating magnitude of the pressure; and
a control unit electrically connected to said sensor units, and including
a detecting module configured to receive the pressure signal from each of said sensor units, and to output a current pressure value corresponding to said pressure signal upon receipt of the pressure signal,
a rate determining module coupled to said detecting module for receiving the current pressure value therefrom, and configured to output a current repetition rate according to the current pressure value, and
a control module coupled to said rate determining module for receiving the current repetition rate therefrom, and configured to output a plurality of key codes corresponding respectively to said keycaps,
wherein, when one of said keycaps is being depressed, said control module is further configured to detect whether the one of said keycaps was previously depressed, to repeatedly output a corresponding one of the key codes at the current repetition rate while the one of said keycaps was previously depressed, and to output the corresponding one of the key codes once while the one of said keycaps was not previously depressed.

2. The keyboard assembly of claim 1, wherein each of said sensor units includes a coil spring disposed under a corresponding one of said keycaps, and a capacitance detecting element located beneath said coil spring,
wherein said coil spring is compressed toward said capacitance detecting element by the corresponding one of said keycaps when the corresponding one of said keycaps is depressed.

3. The keyboard assembly of claim 1, wherein said control unit further includes a flag register module storing a plurality of flags that correspond to said keycaps, respectively,
wherein each of the flags indicates whether a corresponding one of said keycaps was depressed.

4. The keyboard assembly of claim 3, wherein said control module is coupled to said flag register module, and is configured to determine whether each of said keycaps was depressed according to a respective one of the flags.

5. The keyboard assembly of claim 1, wherein said control unit further includes a pressure register module storing a plurality of previous pressure values corresponding to said keycaps, respectively.

6. The keyboard assembly of claim 5, wherein each of the previous pressure values was previously obtained by said detecting module according to the pressure signal that was outputted by a corresponding one of said sensor units when a corresponding one of said keycaps was depressed,
wherein said control module is coupled to said pressure register module, and is further configured to compare the current pressure value with a corresponding one of the previous pressure values, to repeatedly output the corresponding one of the key codes at the current repetition rate when the current pressure value is not the same as the corresponding one of the previous pressure values, and to repeatedly output the corresponding one of the key codes at a previous repetition rate that was previously obtained by said rate determining module according to the corresponding one of the previous pressure values when the current pressure value is the same as the corresponding one of the previous pressure values.

7. The keyboard assembly of claim 1, wherein said control unit further includes a rate register module storing a plurality of previous repetition rates corresponding to said keycaps, respectively.

8. The keyboard assembly of claim 7, wherein each of the previous repetition rates was previously obtained by said rate determining module when a corresponding one of said keycaps was depressed,
wherein said control module is coupled to said rate register module, and is further configured to determine whether to store the current repetition rate in said rate register module for replacing a corresponding one of the previous repetition rates according to the current pressure value.

9. The keyboard assembly of claim 1, wherein said control unit further includes a stopping module configured to store a predetermined value, to receive the current pressure value, and to output a stop signal to said control module for stopping said control module from outputting the corresponding one of the key codes when said the current pressure value is smaller than the predetermined value.

10. The keyboard assembly of claim 1, wherein said detecting module includes an analog-to-digital converter (ADC) for receiving the pressure signal and for converting the pressure signal into the current pressure value.

11. The keyboard assembly of claim 1, further comprising a transmitting unit for receiving the corresponding one of the key codes and for outputting an input signal according to the corresponding one of the key codes.
